(19) United States
(12) Patent Application Publication
(10) Pub. No.: US 2015/0355546 A1
(43) Pub. Date: Dec. 10, 2015

(54) COMPOSITION FOR SILICON-CONTAINING FILM FORMATION, PATTERN-FORMING METHOD, AND POLYSILOXANE COMPOUND

(71) Applicant: JSR CORPORATION, Tokyo (JP)

(72) Inventors: Tomoaki SEKO, Tokyo (JP); Satoshi Dei, Tokyo (JP); Junya Suzuki, Tokyo (JP)

(73) Assignee: JSR CORPORATION, Tokyo (JP)

(21) Appl. No.: 14/728,363

(22) Filed: Jun. 2, 2015

(30) Foreign Application Priority Data
Jun. 5, 2014 (JP) 2014-116877
Apr. 10, 2015 (JP) 2015-081299

(51) Int. Cl. G03F 7/11; G03F 7/20; C08G 77/04; G03F 7/34; C08L 83/04; G03F 7/16; G03F 7/32

(52) U.S. Cl. CPC G03F 7/11; G03F 7/16; G03F 7/20; G03F 7/32; G03F 7/34; C08L 83/04; C08G 77/04; C08L 2203/16

(57) ABSTRACT

A composition for silicon-containing film formation includes a polysiloxane compound and a solvent. The polysiloxane compound includes a structure represented by formula (Q2), a structure represented by formula (Q3) and a structure represented by formula (Q4). A value of q calculated according to formula (I) is no greater than 0.25, wherein q1 to q4 represent integrated intensities of ²⁹Si-NMR signals due to the silicon atoms in the structures represented by the formulae (Q1) to (Q4), respectively. A weight average molecular weight of the polysiloxane compound is no greater than 4,000.

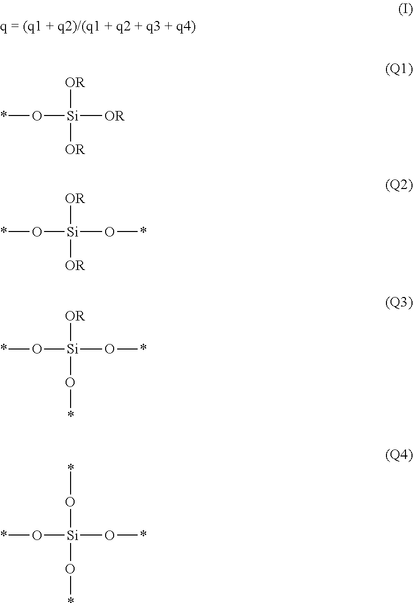

### CROSS-REFERENCE TO RELATED APPLICATIONS

The present application claims priority to Japanese Patent Application No. 2014-116877, filed Jun. 5, 2014, and to Japanese Patent Application No. 2015-081299, filed Apr. 10, 2015. The contents of these applications are incorporated herein by reference in their entirety.

### BACKGROUND OF THE INVENTION

1. Field of the Invention

The present invention relates to a composition for silicon-containing film formation, a pattern-forming method, and a polysiloxane compound.

2. Discussion of the Background

In recent years, miniaturization of semiconductor elements and the like has been accompanied by demands for formation of a finer resist pattern. To meet these demands, various multilayer resist processes have been developed in which a resist underlayer film is used. Such multilayer resist processes are exemplified by a process described as in the following. First, a composition for resist underlayer film formation which contains a polysiloxane is applied on a substrate to provide a resist underlayer film. Next, a photoresist composition is applied on the resist underlayer film to provide a resist film. This resist film is an organic film that is distinct from the resist underlayer film in terms of etching selectivity. Thereafter, the resist film is exposed, and developed with a developer solution to obtain a resist pattern. Subsequently, the resist pattern is transferred to the resist underlayer film and the substrate by way of dry-etching, whereby a substrate having a desired pattern formed thereon can be obtained.

However, when such a conventional composition for resist underlayer film formation is used, collapse of a resist pattern formed on the resist underlayer film, i.e., pattern collapse, as generally referred to, is likely to occur. In addition, the cross-sectional shape of the resist pattern is likely to exhibit a tailing shape. The occurrence of the pattern collapse is significant in negative developments with an organic solvent, and in order to reduce this pattern collapse, use of an additive such as an acid generator has been proposed (see Japanese Unexamined Patent Application, Publication Nos. 2010-85912 and 2008-39811). Further, in order to reduce the tailing of the resist, use of a composition that contains a siloxane compound having a mass average molecular weight falling within a specific range has been proposed (see Japanese Unexamined Patent Application, Publication No. 2007-272168).

### SUMMARY OF THE INVENTION

According to one aspect of the present invention, a composition for silicon-containing film formation includes a polysiloxane compound and a solvent. The polysiloxane compound includes a structure represented by formula (Q2), a structure represented by formula (Q3) and a structure represented by formula (Q4). Each R independently represents a hydrogen atom or a monovalent organic group having 1 to 20 carbon atoms and not containing a silicon atom; and * denotes a binding site to a silicon atom. A value of q calculated according to formula (I) is no greater than 0.25. q1 to q4 represent integrated intensities of ²⁹Si-NMR signals due to the silicon atoms in the structures represented by the formulae (Q1) to (Q4), respectively. A weight average molecular weight of the polysiloxane compound is no greater than 4,000.

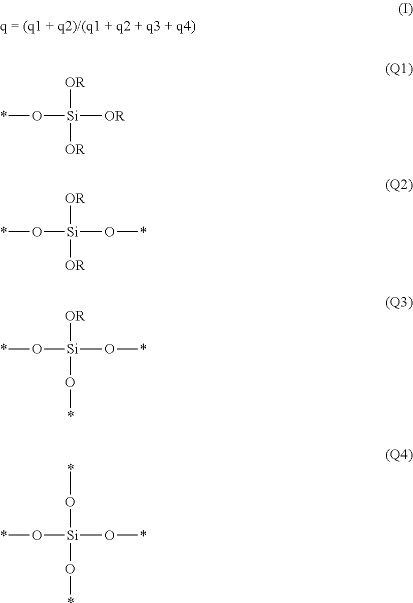

According to another aspect of the present invention, a pattern-forming method includes providing a silicon-containing film directly or indirectly on a substrate by using the composition. A resist film is provided on the silicon-containing film by using a resist composition. The resist film is exposed by irradiation with light through a photomask. The exposed resist film is developed to form a resist pattern. The silicon-containing film and the substrate are sequentially dry-etched using the resist pattern as a mask.

According to further aspect of the present invention, a polysiloxane compound includes a structure represented by the formula (Q2); a structure represented by the formula (Q3); and a structure represented by the formula (Q4). A value of q calculated according to the formula (I) is no greater than 0.25. A weight average molecular weight of the polysiloxane compound is no greater than 4,000.

### DESCRIPTION OF THE PREFERRED EMBODIMENTS

According to an embodiment of the present invention, a composition for silicon-containing film formation contains a polysiloxane compound (hereinafter, may be also referred to as “(A) polysiloxane compound” or “polysiloxane compound (A)”) and a solvent, wherein the polysiloxane compound (A) has a structure represented by the following formula (Q2), a structure represented by the following formula (Q3) and a structure represented by the following formula (Q4) from among structures represented by the following formulae (Q1) to (Q4) (hereinafter, may be also referred to as “structures (Q1) to (Q4)” or “specific siloxane structures”), wherein when integrated intensities of signals due to the silicon atoms in the structures represented by the following formulae (Q1) to (Q4) among signals detected in ²⁹Si-NMR are designated as q1 to q4 respectively, a value of q calculated according to the following formula (I) is no greater than 0.25, and the weight average molecular weight of the polysiloxane compound (A) is no greater than 4,000,

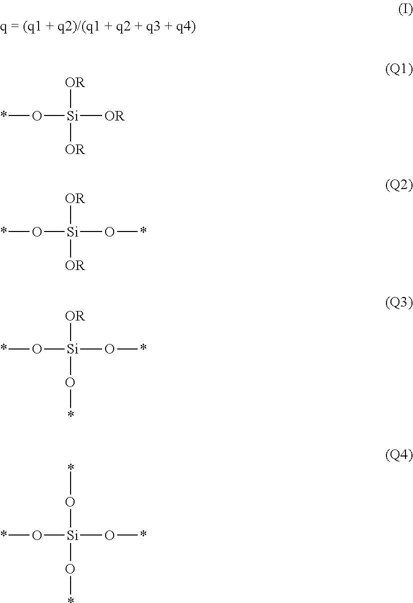

wherein in the formulae (Q1) to (Q4), each R independently represents a hydrogen atom or a monovalent organic group having 1 to 20 carbon atoms and not having a silicon atom; and * denotes a binding site to the silicon atom.

According to another embodiment of the present invention, a pattern-forming method includes: providing a silicon-containing film directly or indirectly on a substrate by using the composition for silicon-containing film formation according to the embodiment of the present invention; providing a resist film on the silicon-containing film by using a resist composition; exposing the resist film by irradiation with light through a photomask; developing the resist film exposed to form a resist pattern; and sequentially dry-etching the silicon-containing film and the substrate by using the resist pattern as a mask.

According to still another embodiment of the present invention, a polysiloxane compound has a structure represented by the above formula (Q2), a structure represented by the above formula (Q3) and a structure represented by the above formula (Q4) among the structures represented by the above formulae (Q1) to (Q4), wherein when integrated intensities of signals due to the silicon atoms in the structures represented by the above formulae (Q1) to (Q4) among signals detected in ²⁹Si-NMR are designated as q1 to q4 respectively, a value of q calculated according to the above formula (I) is no greater than 0.25, and the weight average molecular weight of the polysiloxane compound is no greater than 4,000.

“²⁹Si-NMR” as referred to herein means a nuclear magnetic resonance spectrum of a silicon atom. The “organic group” as referred to means a group that includes at least one carbon atom.

According to the composition for silicon-containing film formation, the pattern-forming method and the polysiloxane compound of the embodiments of the present invention, inhibited pattern collapse and inhibited tailing of the resist as well as superior solvent resistance before curing can be achieved in multilayer resist processes, in particular, in the case of developments with an organic solvent, while superior storage stability is exhibited. Specifically, due to superior solvent resistance before curing, variation of film thicknesses can be reduced. Further, due to superior storage stability, a change of the molecular weight of the polysiloxane during storage of the composition for resist underlayer film formation can be reduced. Therefore, these can be suitably used for pattern formation in manufacture of semiconductor devices, and the like in which further progress of miniaturization is expected in the future. Hereinafter, embodiments of the present invention are explained in detail.

### Composition for Silicon-Containing Film Formation

A composition for silicon-containing film formation according to an embodiment of the present invention contains (A) a polysiloxane compound, and a solvent. Due to containing the polysiloxane compound (A), the composition for silicon-containing film formation enables a film that exhibits superior adhesiveness to a resist film to be formed. Consequently, the pattern collapse of a pattern formed and the tailing of the resist can be reduced. In addition, the composition for silicon-containing film formation may contain optional component(s) such as an acid generator, within a range not leading to impairment of the effects of the present invention. Hereinafter, each component is explained.

### (A) Polysiloxane Compound

The polysiloxane compound (A) has a structure represented by the formula (Q2), a structure represented by the formula (Q3) and a structure represented by the formula (Q4) among the specific siloxane structures. In addition, when integrated intensities of signals due to the silicon atoms in the specific siloxane structures among signals detected in ²⁹Si-NMR are designated as q1 to q4 respectively, a value of q calculated according to the following formula (I) is no greater than 0.25, and the weight average molecular weight of the polysiloxane compound (A) is no greater than 4,000.

q=(q1+q2)/(q1+q2+q3+q4) (I)

Due to the polysiloxane compound (A) having the aforementioned structure, the value of q being no greater than 0.25, and the weight average molecular weight of the polysiloxane compound (A) being no greater than 4,000, the composition for silicon-containing film formation exhibits superior storage stability, inhibited pattern collapse and inhibited tailing of a pattern, and superior solvent resistance before curing.

The value of q is typically no less than 0.01. The upper limit of the value of q is 0.25, as described above, preferably 0.2, and more preferably 0.15. When the value of q is less than the upper limit, the storage stability may be further improved, the pattern collapse and the tailing of a pattern may be further inhibited, and further superior solvent resistance before curing may be exhibited.

In the above in the formulae (Q1) to (Q4), R represents a hydrogen atom or a monovalent organic group having 1 to 20 carbon atoms and not having a silicon atom; and * denotes a binding site to the silicon atom. When R represents an organic group, R bonds to an oxygen atom adjacent to the silicon atom at a carbon atom of the organic group. Examples of the monovalent organic group having 1 to 20 carbon atoms which may be represented by R include groups similar to organic groups exemplified in connection with X described later, and the like. According to the specific siloxane structures, the binding site denoted by * on the oxygen atom bonds to other silicon atom in the polysiloxane compound (A). The other silicon atom may be included in the specific siloxane structures. In this instance, adjacent specific siloxane structures share the oxygen atom.

Although not necessarily clarified, the reason for achieving the effects described above resulting from the composition for silicon-containing film formation having the aforementioned constitution is presumed to be as in the following. Specifically, since the proportions of the amount of the structure (Q1) and the structure (Q2) are small, the structure of the polysiloxane compound (A) would have high regularity, and consequently the degree of alignment and the density of the polar group would be increased. In addition, since the weight average molecular weight of the polysiloxane compound (A) is no greater than the aforementioned upper limit, the specific siloxane structures would be more uniformly distributed in the composition for silicon-containing film formation which contains the polysiloxane compound (A), leading to a further increase of the regularity. Consequently, the siloxane structure included in the polysiloxane compound (A) would interact with a carboxy group or the like in the resist film, leading to an improvement of adhesiveness of the silicon-containing film that contains the polysiloxane compound (A) to the resist film. As a result, the pattern collapse and the tailing would be inhibited. Moreover, the stability of the composition for silicon-containing film formation would be improved due to the uniform distribution of the specific siloxane structures, and consequently the solvent resistance before curing and the storage stability of the composition for silicon-containing film formation would be improved. The “siloxane structure” as referred to herein means a structure that includes —Si—O—.

Moreover, the lower limit of a value of q′ represented by the following formula (II) is preferably 0.2, and more preferably 0.25. On the other hand, the upper limit of the value of q′ is preferably 0.7, and more preferably 0.6. It is to be noted that in the following formula (II), q1 to q4 are as defined in the above formula (I).

q′=(q4)/(q1+q2+q3+q4) (II)

Thus, when the proportion of the amount of the structure (Q4) with respect to the total amount of the specific siloxane structures falls within the above range, the regularity of the polysiloxane compound (A) described above may be further increased, and consequently the pattern collapse and the tailing may be further inhibited.

It is to be noted that an integrated intensity of a signal detected by ²⁹Si-NMR as referred to herein is determined using a nuclear magnetic resonance apparatus available from Bruker BioSpin K.K., for example.

The lower limit of the proportion of the amount of the silicon atoms in the specific siloxane structures with respect to the total amount of silicon atoms included in the polysiloxane compound (A) is preferably 50 mol %, more preferably 60 mol %, and still more preferably 70 mol %. When the proportion of the amount of the silicon atoms in the specific siloxane structures is no less than the aforementioned lower limit, the regularity of the structure of the polysiloxane compound (A) may be further improved, and consequently the pattern collapse and the tailing may be further inhibited.

### Synthesis Method of Polysiloxane Compound

In regard to the synthesis method of the polysiloxane compound (A), a method in which a compound represented by the following formula (1) (hereinafter, may be also referred to as “compound (I)”) is subjected to condensation using an acid is preferred. The acid causes Z⁺ in the compound (I) to be replaced by a hydrogen atom, leading to generation of a silanol form, and thereafter the condensation reaction takes place.

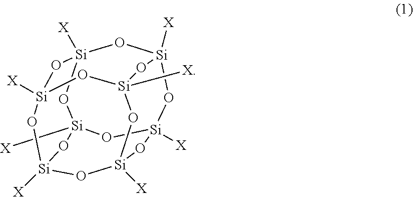

In the above formula (1), X represents —O⁻Z⁺ or a monovalent organic group having 1 to 20 carbon atoms; and Z⁺ represents a monovalent cation.

The monovalent organic group having 1 to 20 carbon atoms which may be represented by X is exemplified by: a monovalent hydrocarbon group such as a chain hydrocarbon group, an alicyclic hydrocarbon group and an aromatic hydrocarbon group; a group that includes a hetero atom-containing group between two carbon atoms of the monovalent hydrocarbon group; a group obtained by substituting a part or all of hydrogen atoms included in these groups with a substituent; and the like.

Examples of the chain hydrocarbon group include:

alkyl groups such as a methyl group, an ethyl group, a propyl group and a butyl group;

alkenyl groups such as an ethenyl group, a propenyl group and a butenyl group;

alkynyl groups such as an ethynyl group, a propynyl group and a butynyl group; and the like.

Examples of the alicyclic hydrocarbon group include:

cycloalkyl groups such as a cyclopropyl group, a cyclopentyl group, a cyclohexyl group, a norbornyl group and an adamantyl group;

cycloalkenyl groups such as a cyclopropenyl group, a cyclopentenyl group, a cyclohexenyl group and a norbornenyl group; and the like.

Examples of the aromatic hydrocarbon group include:

aryl groups such as a phenyl group, a tolyl group, a xylyl group, a naphthyl group and an anthryl group;

aralkyl groups such as a benzyl group, a phenethyl group and a naphthylmethyl group; and the like.

The hetero atom-containing group as referred to means a group that has a hetero atom having a valency of no less than 2 in the structure thereof. The hetero atom-containing group may have either one, or two or more hetero atom(s).

The hetero atom having a valency of no less than 2 which may be included in the hetero atom-containing group is not particularly limited as long as the hetero atom has an atomic valence of no less than 2, and examples thereof include an oxygen atom, a nitrogen atom, a sulfur atom, a silicon atom, a phosphorus atom, a boron atom, and the like.

Examples of the hetero atom-containing group include:

groups constituted with only hetero atom(s), such as —SO—, —SO₂—, —SO₂O—, and —SO₃—;

groups obtained by combining at least one carbon atom(s) with at least one hetero atom(s), such as —CO—, —COO—, —COS—, —CONH—, —OCOO—, —OCOS—, —OCONH—, —SCONH—, —SCSNH—, and —SCSS—; and the like.

Examples of the substituent include halogen atoms, a hydroxy group, a carboxy group, a nitro group, a cyano group, and the like.

Examples of the monovalent cation represented by Z⁺ include ions of alkali metals such as lithium, sodium, potassium and cesium; onium ions such as ammonium ions and sulfonium ions; and the like. Of these, onium ions are preferred, ammonium ions are more preferred, and quaternary ammonium ions are still more preferred.

X represents preferably —O⁻Z⁺, an alkyl group having 1 to 20 carbon atoms, a monovalent aromatic hydrocarbon group having 6 to 20 carbon atoms, or a hetero atom-containing monovalent alicyclic hydrocarbon group having 3 to 20 carbon atoms, more preferably —O⁻Z⁺, a methyl group, a phenyl group, an alkylphenyl group, or a group that includes a cyclic acid anhydride structure, and still more preferably —O⁻Z⁺ or a phenyl group.

Examples of the acid for use in the synthesis of the polysiloxane compound (A) include: inorganic acids such as hydrochloric acid, sulfuric acid, nitric acid and phosphoric acid; and organic acids such as acetic acid, oxalic acid, maleic acid, formic acid, trifluoroacetic acid and trifluoromethanesulfonic acid. Of these, organic acids are preferred, carboxylic acids are more preferred, and oxalic acid and maleic acid are still more preferred.

In light of acceleration of the condensation reaction, the amount of the acid used in the reaction with respect to 1 mol of the compound (1) is preferably no greater than 0.2 mol, and more preferably no less than 0.00001 mol and no greater than 0.1 mol.

Although the reaction solvent which may be used in the condensation reaction is not particularly limited, solvents similar to those for use in the preparation of the composition for silicon-containing film formation described later may be typically used. Of these, methanol, butanol, diethylene glycol dimethyl ether, diethylene glycol ethyl methyl ether, propylene glycol monomethyl ether, propylene glycol monoethyl ether, propylene glycol monomethyl ether acetate, and methyl 3-methoxypropionate are preferred.

The lower limit of the temperature of the reaction of the compound (I) with the acid is preferably 0° C. On the other hand, the upper limit of the temperature of the reaction is preferably 15° C., and more preferably 10° C. The lower limit of the time period of the reaction of the compound (I) with the acid is preferably 15 min, and more preferably 30 min. On the other hand, the upper limit of the time period of the reaction is preferably 24 hrs, and more preferably 12 hrs. When the reaction temperature and the reaction time period each fall within the above range, the condensation reaction may efficiently occur.

Synthesis Method of Compound (I)

The synthesis method of the compound (I) is not particularly limited, and examples thereof include a method in which a tetrafunctional hydrolyzable silane compound is allowed to react with a high concentration of a base and thereby hydrolytic condensation thereof is achieved.

Examples of the tetrafunctional hydrolyzable silane compound include: tetraalkoxysilanes such as tetramethoxysilane, tetraethoxysilane, tetra-n-propoxysilane, tetra-iso-propoxysilane, tetra-n-butoxysilane, tetra-sec-butoxysilane and tetra-t-butoxysilane; tetraarylsilanes such as tetraphenoxysilane; and the like. Of these, tetraalkoxysilanes are preferred, and tetramethoxysilane is more preferred.

Examples of the base include: nitrogen-containing compounds such as ammonia, primary amines, secondary amines, tertiary amines and pyridine; basic ion exchange resins; hydroxides such as sodium hydroxide; carbonates such as potassium carbonate; carboxylic acid salts such as sodium acetate; alkoxides such as zirconium alkoxides, titanium alkoxides and aluminum alkoxides; and the like. Of these, quaternary ammonium salts are preferred, and tetrahydromethylammonium hydroxide is more preferred.

In light of acceleration of the hydrolytic condensation reaction, the amount of the base used in the reaction with respect to 1 mol of the tetrafunctional hydrolyzable silane compound is preferably no greater than 2 mol, and more preferably no less than 0.8 mol and no greater than 1.2 mol.

Water purified according to a procedure such as a reverse osmosis membrane treatment, an ion exchange treatment or distillation is preferably used in the hydrolytic condensation. When such purified water is used, side reaction(s) may be inhibited, and accordingly the reaction efficiency of the hydrolysis may be improved. The lower limit of the amount of water used with respect to 1 mol in total of the hydrolyzable group of the silane compound is preferably 0.1 mol, more preferably 0.3 mol, and still more preferably 0.5 mol. On the other hand, the upper limit of the amount of water used is preferably 3 mol, more preferably 2 mol, and still more preferably 1.5 mol. When the amount of water used falls within the above range, the rate of the hydrolytic condensation may be optimized.

The reaction solvent which may be used in the hydrolytic condensation is not particularly limited, and solvents similar to those for use in the preparation of the composition for silicon-containing film formation described later may be typically used. Of these, methanol, butanol, diethylene glycol dimethyl ether, diethylene glycol ethyl methyl ether, propylene glycol monomethyl ether, propylene glycol monoethyl ether, propylene glycol monomethyl ether acetate, and methyl 3-methoxypropionate are preferred.

The reaction temperature and the reaction time period in the hydrolytic condensation are appropriately selected. The lower limit of the reaction temperature is preferably 40° C., and more preferably 50° C. On the other hand, the upper limit of the reaction temperature is preferably 200° C., and more preferably 150° C. The lower limit of the reaction time period is preferably 30 min, and more preferably 1 hour. On the other hand, the upper limit of the reaction time period is preferably 24 hrs, and more preferably 12 hrs. When the reaction temperature and the reaction time period each fall within the above range, the hydrolytic condensation reaction may occur highly efficiently. In regard to the hydrolytic condensation, the tetrafunctional hydrolyzable silane compound, water and a catalyst may be added to a reaction mixture in one portion and then the reaction may be allowed to proceed in one step. Alternatively, the tetrafunctional hydrolyzable silane compound, water and a catalyst may be added to a reaction mixture in several portions, and the hydrolytic condensation reaction may be allowed to proceed in multiple steps. It is to be noted that water and the alcohol formed can be removed from the reaction system after the hydrolytic condensation reaction by subjecting the reaction mixture to evaporation.

In addition, in the condensation reaction and the hydrolytic condensation, a trifunctional hydrolyzable silane compound may be added. When the trifunctional hydrolyzable silane compound is thus added, optical characteristics and etching resistance of a silicon-containing film that contains the polysiloxane compound (A) can be controlled, and consequently a resolution and the like of the resist pattern formed may be improved.

The trifunctional hydrolyzable silane compound is exemplified by an aromatic ring-containing trialkoxysilane, an alkyltrialkoxysilane, an alkenyltrialkoxysilane, an epoxy group-containing silane, an acid anhydride group-containing silane, and the like.

Examples of the aromatic ring-containing trialkoxysilane include phenyltrimethoxysilane, benzyltrimethoxysilane, phenethyltrimethoxysilane, 4-methylphenyltrimethoxysilane, 4-ethylphenyltrimethoxysilane, 4-methoxyphenyltrimethoxysilane, 4-phenoxyphenyltrimethoxysilane, 4-hydroxyphenyltrimethoxysilane, 4-aminophenyltrimethoxysilane, 4-dimethylaminophenyltrimethoxysilane, 4-acetylaminophenyltrimethoxysilane, 3-methylphenyltrimethoxysilane, 3-ethylphenyltrimethoxysilane, 3-methoxyphenyltrimethoxysilane, 3-phenoxyphenyltrimethoxysilane, 3-hydroxyphenyltrimethoxysilane, 3-aminophenyltrimethoxysilane, 3-dimethylaminophenyltrimethoxysilane, 3-acetylaminophenyltrimethoxysilane, 2-methylphenyltrimethoxysilane, 2-ethylphenyltrimethoxysilane, 2-methoxyphenyltrimethoxysilane, 2-phenoxyphenyltrimethoxysilane, 2-hydroxyphenyltrimethoxysilane, 2-aminophenyltrimethoxysilane, 2-dimethylaminophenyltrimethoxysilane, 2-acetylaminophenyltrimethoxysilane, 2,4,6-trimethylphenyltrimethoxysilane, 4-methylbenzyltrimethoxysilane, 4-ethylbenzyltrimethoxysilane, 4-methoxybenzyltrimethoxysilane, 4-phenoxybenzyltrimethoxysilane, 4-hydroxybenzyltrimethoxysilane, 4-aminobenzyltrimethoxysilane, 4-dimethylaminobenzyltrimethoxysilane, 4-acetylaminobenzyltrimethoxysilane, and the like.

Examples of the alkyltrialkoxysilane include methyltrimethoxysilane, methyltriethoxysilane, methyltri-n-propoxysilane, methyltri-iso-propoxysilane, methyltri-n-butoxysilane, methyltri-sec-butoxysilane, methyltri-t-butoxysilane, methyltriphenoxysilane, methyltriacetoxysilane, methyltrichlorosilane, methyltriisopropenoxysilane, methyltris(dimethylsiloxy)silane, methyltris(methoxyethoxy)silane, methyltris(methylethylketoxime)silane, methyltris(trimethylsiloxy)silane, methylsilane, ethyltrimethoxysilane, ethyltriethoxysilane, ethyltri-n-propoxysilane, ethyltri-iso-propoxysilane, ethyltri-n-butoxysilane, ethyltri-sec-butoxysilane, ethyltri-t-butoxysilane, ethyltriphenoxysilane, ethyltris(trimethylsiloxy)silane, ethyldichlorosilane, ethyltriacetoxysilane, ethyltrichlorosilane, n-propyltrimethoxysilane, n-propyltriethoxysilane, n-propyltri-n-propoxysilane, n-propyltri-iso-propoxysilane, n-propyltri-n-butoxysilane, n-propyltri-sec-butoxysilane, n-propyltri-t-butoxysilane, n-propyltriphenoxysilane, n-propyltriacetoxysilane, n-propyltrichlorosilane, iso-propyltrimethoxysilane, iso-propyltriethoxysilane, iso-propyltri-n-propoxysilane, iso-propyltri-iso-propoxysilane, iso-propyltri-n-butoxysilane, iso-propyltri-sec-butoxysilane, iso-propyltri-t-butoxysilane, iso-propyltriphenoxysilane, n-butyltrimethoxysilane, n-butyltriethoxysilane, n-butyltri-n-propoxysilane, n-butyltri-iso-propoxysilane, n-butyltri-n-butoxysilane, n-butyltri-sec-butoxysilane, n-butyltri-t-butoxysilane, n-butyltriphenoxysilane, n-butyltrichlorosilane, 2-methylpropyltrimethoxysilane, 2-methylpropyltriethoxysilane, 2-methylpropyltri-n-propoxysilane, 2-methylpropyltri-iso-propoxysilane, 2-methylpropyltri-n-butoxysilane, 2-methylpropyltri-sec-butoxysilane, 2-methylpropyltri-t-butoxysilane, 2-methylpropyltriphenoxysilane, 1-methylpropyltrimethoxysilane, 1-methylpropyltriethoxysilane, 1-methylpropyltri-n-propoxysilane, 1-methylpropyltri-iso-propoxysilane, 1-methylpropyltri-n-butoxysilane, 1-methylpropyltri-sec-butoxysilane, 1-methylpropyltri-t-butoxysilane, 1-methylpropyltriphenoxysilane, t-butyltrimethoxysilane, t-butyltriethoxysilane, t-butyltri-n-propoxysilane, t-butyltri-iso-propoxysilane, t-butyltri-n-butoxysilane, t-butyltri-sec-butoxysilane, t-butyltri-t-butoxysilane, t-butyltriphenoxysilane, t-butyltrichlorosilane, t-butyldichlorosilane, and the like.

Examples of the alkenyltrialkoxysilane include vinyltrimethoxysilane, vinyltriethoxysilane, vinyltri-n-propoxysilane, vinyltriisopropoxysilane, vinyltri-n-butoxysilane, vinyltri-sec-butoxysilane, vinyltri-t-butoxysilane, vinyltriphenoxysilane, allyltrimethoxysilane, allyltriethoxysilane, allyltri-n-propoxysilane, allyltriisopropoxysilane, allyltri-n-butoxysilane, allyltri-sec-butoxysilane, allyltri-t-butoxysilane, allyltriphenoxysilane, and the like.

Examples of the epoxy group-containing silane include oxetanyltrimethoxysilane, oxiranyltrimethoxysilane, oxiranylmethyltrimethoxysilane, 3-glycidyloxypropyltrimethoxysilane, and the like.

Examples of the acid anhydride group-containing silane include 2-[3-(trimethoxysilyl)propyl]succinic anhydride, 2-(trimethoxysilyl)ethylsuccinic anhydride, 3-(trimethoxysilyl)propylmaleic anhydride, 2-(trimethoxysilyl)ethylglutaric anhydride, and the like.

The trifunctional hydrolyzable silane compound is preferably an aromatic ring-containing trialkoxysilane, an alkyltrialkoxysilane, or an acid anhydride group-containing silane, and more preferably phenyltrimethoxysilane, benzyltrimethoxysilane, 4-methylphenyltrimethoxysilane, methyltrimethoxysilane, methyltriethoxysilane, or 2-[3-(trimethoxysilyl)propyl]succinic anhydride.

The lower limit of the amount of the trifunctional hydrolyzable silane compound added with respect to 100 parts by mass of the tetrafunctional hydrolyzable silane compound is preferably 1 part by mass, and more preferably 3 parts by mass. On the other hand, the upper limit of the amount of the trifunctional hydrolyzable silane compound added is preferably 15 parts by mass, and more preferably 12 parts by mass. When the amount of the trifunctional hydrolyzable silane compound falls within the above range, optical performances and the like of the silicon-containing film can be controlled more certainly.

Moreover, the lower limit of the proportion of the amount of the tetrafunctional hydrolyzable silane compound with respect to the total amount of the hydrolyzable silane compounds used in the synthesis of the polysiloxane compound (A) is preferably 50 mol %, more preferably 60 mol %, and still more preferably 70 mol %. When the proportion of the amount of the tetrafunctional hydrolyzable silane compound is no less than the lower limit, the regularity of the structure of the polysiloxane compound (A) may be further improved, leading to further inhibition of the pattern collapse and the tailing, and the solvent resistance and the storage stability before curing can be further improved.

The synthesis method of the polysiloxane compound (A) in which the tetrafunctional hydrolyzable silane compound is tetramethoxysilane, and the trifunctional hydrolyzable silane compound is phenyltrimethoxysilane may be represented by the following scheme.

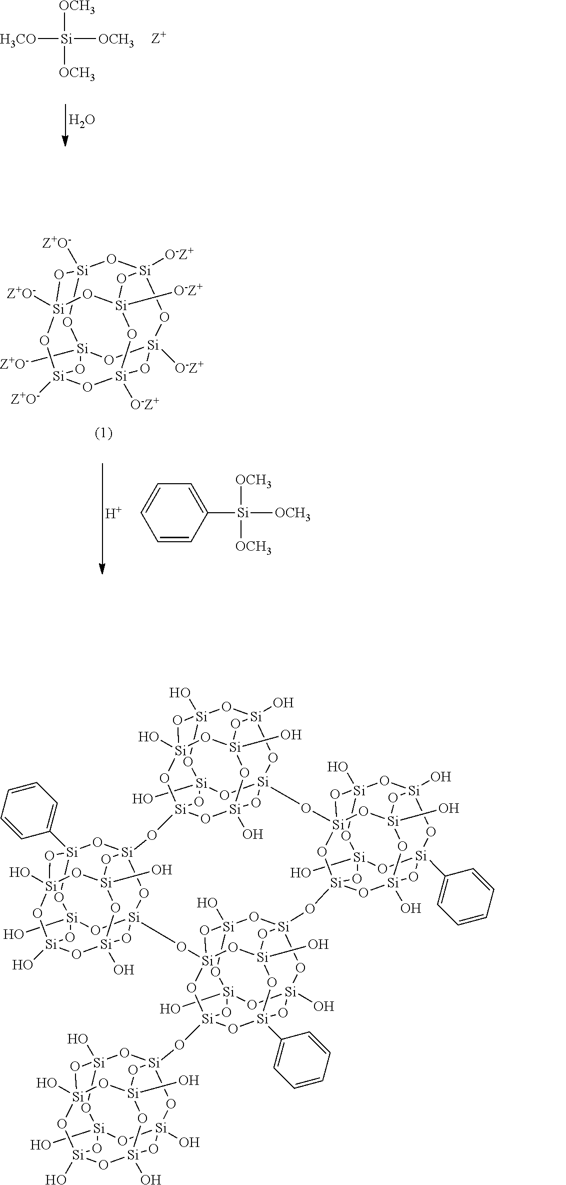

In the above scheme, Z⁺ represents a monovalent cation.

The compound (1) can be obtained by allowing the tetramethoxysilane to react in a solvent, with the monovalent cation derived from the base and represented by Z. When an acid and phenyltrimethoxysilane are added to the reaction liquid, H⁺ derived from the acid causes substitution of Z⁺ of the compound (1) with a hydrogen atom to generate a silanol form. Thereby, the molecules of the compound (1) in the silanol form are condensed with each other. Concurrently, replacement by phenyltrimethoxysilane through hydrolytic condensation occurs to give a polymer represented by the above formula (2).

Although phenyltrimethoxysilane is added after the generation of the compound (1) in the above scheme, phenyltrimethoxysilane may be added to tetramethoxysilane. In this instance, a compound (hereinafter, may be also referred to as “compound (1′)”) which is a compound (1) in which a part of the groups represented by —O⁻Z⁺ are substituted with a phenyl group is formed concurrently with the formation of the compound (1). Thereafter, the compound (1) and the compound (1′) are condensed by an action of the acid to obtain the polymer represented by the above formula (2).

The lower limit of the polystyrene equivalent weight average molecular weight (Mw) of the polysiloxane compound (A) as determined by gel permeation chromatography (GPC) is preferably 800, more preferably 1,000, and still more preferably 1,200. On the other hand, the upper limit of the Mw is 4,000, preferably 3,500, and more preferably 3,200. When the Mw is less than the lower limit, the strength of the silicon-containing film that contains the polysiloxane compound (A) may be deteriorated. To the contrary, when the Mw is greater than the upper limit, uniformity of the distribution of the specific siloxane structures in the composition for silicon-containing film formation is less likely to be improved.

It is to be noted that the Mw as used herein is determined by gel permeation chromatography (GPC) using: GPC columns (for example, “G2000 HXL×2, G3000 HXL×1, and G4000 HXL×1” available from Tosoh Corporation); and mono-dispersed polystyrene as a standard, under an analytical condition involving a flow rate of 1.0 mL/min, an elution solvent of tetrahydrofuran, and a column temperature of 40° C.

The content of the polysiloxane compound (A) with respect to the total solid content in the composition for silicon-containing film formation is typically no less than 80% by mass, preferably no less than 85% by mass, and more preferably no less than 90% by mass. When the content of the polysiloxane compound (A) is less than the lower limit, hardness of the formed silicon-containing film may be deteriorated. It is to be noted that the “solid content” as referred to herein means a residue left after eliminating volatile substances from a sample by drying the sample on a hot plate at 175° C. for 1 hour.

### Solvent

The solvent may be used without any particular limitation as long as it can dissolve or disperse the polysiloxane compound (A) and optional component(s). The solvent is exemplified by: organic solvents such as an alcohol solvent, an ether solvent, a ketone solvent, an amide solvent, an ester solvent, a hydrocarbon solvent; and the like.

Examples of the alcohol solvent include:

aliphatic monohydric alcohol solvents having 1 to 18 carbon atoms, such as methanol, ethanol, propanol, methylisobutylcarbinol and n-hexanol;

alicyclic monohydric alcohol solvents having 3 to 18 carbon atoms, such as cyclohexanol;

polyhydric alcohol solvents having 3 to 18 carbon atoms, such as 1,2-propylene glycol;

polyhydric alcohol partial ether solvents having 3 to 19 carbon atoms, such as propylene glycol monoethyl ether; and the like.

Examples of the ether solvent include:

dialiphatic ether solvents such as diethyl ether, dipropyl ether and dibutyl ether;

aromatic ring-containing ether solvents such as anisole and diphenyl ether;

cyclic ether solvents such as tetrahydrofuran and dioxane: and the like.

Examples of the ketone solvent include:

chain ketone solvents such as acetone, methyl ethyl ketone, methyl n-propyl ketone, methyl n-butyl ketone, diethyl ketone, methyl iso-butyl ketone, methyl n-amyl ketone, ethyl n-butyl ketone, methyl n-hexyl ketone, di-iso-butyl ketone, trimethylnonanone and acetophenone;

cyclic ketone solvents such as cyclopentanone, cyclohexanone, cycloheptanone, cyclooctanone and methylcyclohexanone;

diketone solvents such as 2,4-pentanedione and acetonylacetone; and the like.

Examples of the amide solvent include:

chain amide solvents such as N-methylformamide, N,N-dimethylformamide, N,N-diethylformamide, acetamide, N-methylacetamide, N,N-dimethylacetamide and N-methylpropionamide;

cyclic amide solvents such as N-methylpyrrolidone and N,N′-dimethylimidazolidinone; and the like.

Examples of the ester solvent include:

monocarboxylic acid ester solvents such as n-butyl acetate and ethyl lactate;

lactone solvents such as γ-butyrolactone and valerolactone;

polyhydric alcohol partially etherified carboxylate solvents such as propylene glycol monomethyl ether acetate;

polyhydric carboxylic acid diester solvents such as diethyl oxalate; carbonate solvents such as dimethyl carbonate and diethyl carbonate;

and the like.

Examples of the hydrocarbon solvent include:

aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane;

aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene;

halogen-containing solvents such as dichloromethane, chloroform, chlorofluorocarbons, chlorobenzene and dichlorobenzene; and the like.

Of these, as the solvent, an alcohol solvent and an ester solvent are preferred, a polyhydric alcohol partial ether solvent and a polyhydric alcohol monoalkyl ether acetate solvent are more preferred, and propylene glycol monoethyl ether and propylene glycol monomethyl ether acetate are still more preferred. These solvents may be used either alone, or two or more types thereof may be used in combination.

The composition for silicon-containing film formation may contain water. When the composition for silicon-containing film formation contains water, the storage stability thereof may be improved due to hydration of the polysiloxane compound (A). In addition, when the composition for silicon-containing film formation contains water, curing in forming a resist underlayer film may be accelerated, whereby a compact film can be obtained. In the case where the composition for silicon-containing film formation contains water, the lower limit of the percentage content of water is preferably 0.1% by mass, and more preferably 0.2% by mass. On the other hand, the upper limit of the percentage content is preferably 30% by mass, more preferably 20% by mass, and still more preferably 15% by mass. When the content of water is greater than the upper limit, the storage stability of the composition for silicon-containing film formation may be deteriorated, and/or uniformity of the formed film may also be deteriorated.

### Optional Component

Optional component which may be contained in the composition for silicon-containing film formation is exemplified by an acid generating agent, a nitrogen-containing compound, β-diketone, colloidal silica, colloidal alumina, an organic polymer, a surfactant, a base generator, and the like.

### Acid Generating Agent

The acid generating agent is a component that generates an acid upon an exposure or heating. When the resin composition for silicon-containing film formation contains the acid generating agent, a crosslinking reaction can effectively occur between molecular chains of the polysiloxane compound (A) and the like at comparatively low temperatures including normal temperatures.

An acid generating agent that generates an acid upon an exposure (hereinafter, may be also referred to as “photoacid generating agent”) is exemplified by acid generating agents disclosed in paragraphs [0077] to [0081] of Japanese Unexamined Patent Application, Publication No. 2004-168748, and the like.

Moreover, an acid generating agent that generates an acid upon heating (hereinafter, may be also referred to as “thermal acid generating agent”) is exemplified by 2,4,4,6-tetrabromocyclohexadienone, benzoin tosylate, 2-nitrobenzyl tosylate, alkylsulfonates, and the like in addition to the onium salt-type acid generating agents exemplified in connection with the photoacid generating agent described above.

The acid generating agent is preferably an onium salt-type acid generating agent, more preferably a sulfonium salt-type acid generating agent, and an iodonium salt-type acid generating agent, and still more preferably triphenylsulfonium nonafluoro-n-butane-1-sulfonate, triphenylsulfonium 2-(adamantan-1-yl)-1,1-difluoroethane-1-sulfonate, triphenylsulfonium adamantan-1-yloxycarbonyl-1,1-difluoromethanesulfonate, triphenylsulfonium norbornanesulton-2-yloxycarbonyl-1,1-difluoromethanesulfonate, and di(t-butylphenyl)iodonium nonafluorobutanesulfonate.

The upper limit of the content of the acid generating agent with respect to 100 parts by mass of the polysiloxane compound (A) is preferably 20 parts by mass, and more preferably 10 parts by mass. One, or two or more types of the acid generating agent may be used.

Nitrogen-Containing Compound

The nitrogen-containing compound is a compound that includes a basic amino group, or a compound that includes a group capable of being converted to a basic amino group by an action of an acid. The nitrogen-containing compound achieves an effect of improving characteristics such as ashing resistance of the silicon-containing film obtained from the composition for silicon-containing film formation. This effect is believed to be derived from acceleration of the crosslinking reaction in the silicon-containing film due to the presence of the nitrogen-containing compound in the silicon-containing film.

The nitrogen-containing compound is exemplified by an amine compound, an amide group-containing compound, a urea compound, a nitrogen-containing heterocyclic compound, and the like.

Examples of the amine compound include mono(cyclo)alkylamines; di(cyclo)alkylamines; tri(cyclo)alkylamines; substituted alkylanilines and derivatives thereof; ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl)ether, bis(2-diethylaminoethyl)ether, 1-(2-hydroxyethyl)-2-imidazolidinone, 2-quinoxalinol, N,N,N′,N′-tetrakis(2-hydroxypropyl)ethylenediamine, N,N,N′,N″,N″-pentamethyldiethylenetriamine, and the like.

Examples of the amide group-containing compound include N-t-butoxycarbonyl group-containing amino compound, N-t-amyloxycarbonyl group-containing amino compound, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl) isocyanurate, and the like.

Examples of the urea compound include urea, methylurea, 1,1-dimethylurea, 1,3-dimethylurea, 1,1,3,3-tetramethylurea, 1,3-diphenyl urea, tri-n-butylthiourea, and the like.

Examples of the nitrogen-containing heterocyclic compound include imidazoles; pyridines; piperazines; pyrazine, pyrazole, pyridazine, quinoxaline, purine, pyrrolidine, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, and the like.

Of these, the nitrogen-containing compound is preferably an amide group-containing compound, and more preferably N-t-butoxycarbonyl group-containing amino compound, and N-t-amyloxycarbonyl group-containing amino compound.

In light of achieving favorable pattern configuration, the upper limit of the content of the nitrogen-containing compound with respect to 100 parts by mass of the polysiloxane compound (A) is typically 30 parts by mass, preferably 10 parts by mass, and more preferably 1 part by mass. One, or two or more types of the nitrogen-containing compound may be used.

### Preparation Method of Composition for Silicon-Containing Film Formation

The composition for silicon-containing film formation according to the embodiment of the present invention may be obtained, for example, by mixing the polysiloxane compound (A) with the optional component(s), as needed, and dissolving or dispersing the same in a solvent, optionally after the polysiloxane compound (A) with the optional component(s). The lower limit of the solid content concentration of the composition for silicon-containing film formation is preferably 0.5% by mass, and more preferably 1% by mass. On the other hand, the upper limit of the solid content concentration is preferably 20% by mass, and more preferably 10% by mass.

Since the composition for silicon-containing film formation enables the pattern collapse and the tailing of a resist to be inhibited as described above, the composition for silicon-containing film formation can be suitably used in the pattern-forming method described below, or the like for forming a resist underlayer film.

### Pattern-Forming Method

A pattern-forming method according to another embodiment of the present invention includes: providing a silicon-containing film directly or indirectly on a substrate by using the composition for silicon-containing film formation according to the embodiment of the present invention (hereinafter, may be also referred to as “silicon-containing film-providing step”); providing a resist film on the silicon-containing film by using a resist composition (hereinafter, may be also referred to as “resist film-providing step”); exposing the resist film by irradiation with light through a photomask (hereinafter, may be also referred to as “exposure step”); developing the resist film exposed to form a resist pattern (hereinafter, may be also referred to as “development step”); and sequentially dry-etching the silicon-containing film and the substrate by using the resist pattern as a mask (hereinafter, may be also referred to as “dry-etching step”). Hereinafter, each step is explained.

### Silicon-Containing Film-Providing Step

In the silicon-containing film-providing step, the composition for silicon-containing film formation is applied onto a substrate, followed by heating to cause crosslinking of the polysiloxane, whereby the silicon-containing film is provided.

As the substrate, a conventionally well-known substrate, e.g., a silicon wafer, a wafer coated with aluminum, or the like may be used.

The application procedure of the composition for silicon-containing film formation is exemplified by spin-coating, cast coating, roll coating, and the like. Moreover, the film thickness of the silicon-containing film provided is typically no less than 0.01 μm and no greater than 1 μm, and preferably no less than 0.01 μm and no greater than 0.5 μm.

After the composition for silicon-containing film formation is applied, prebaking (PB) may be executed to evaporate the solvent in the coating film, as needed. The PB temperature may be appropriately selected depending on the formulation of the composition for silicon-containing film formation, but is typically no less than 30° C. and no greater than 200° C. In addition, the PB time period is typically no less than 5 sec and no greater than 600 sec.

The lower limit of the temperature of the heating after applying the composition for silicon-containing film formation is not particularly limited, but preferably 100° C., more preferably 120° C., still more preferably 150° C., and particularly preferably 200° C. On the other hand, the upper limit of the temperature of the heating is preferably 450° C., more preferably 400° C., still more preferably 300° C., and particularly preferably 240° C. The lower limit of the time period of the heating is preferably 10 sec, more preferably 15 sec, still more preferably 20 sec, and particularly preferably 40 sec. On the other hand, the upper limit of the time period of the heating is preferably 1 hour, more preferably 10 min, still more preferably 150 sec, and particularly preferably 80 sec. When the temperature and time period of the heating in providing the silicon-containing film each fall within the above range, the silicon-containing film can be formed conveniently and certainly. In addition, the atmosphere during the heating is not particularly limited, and the heating may be executed under an air atmosphere, or under an atmosphere of an inert gas such as a nitrogen gas.

Moreover, a resist underlayer film which is an organic film may be provided on the substrate before the silicon-containing film-providing step, and in the silicon-containing film-providing step, the silicon-containing film may be provided on the resist underlayer film. In multilayer resist processes, when the resist underlayer film which is an organic film is provided between the substrate and the silicon-containing film, the effects of the present invention can be further enhanced. The resist underlayer film can be typically provided by applying a composition for organic underlayer film formation, followed by drying.

Further, an organic antireflective film may be provided on the substrate, and the silicon-containing film or the like may be provided thereon. Antireflective films disclosed, for example, in Japanese Examined Patent Application, Publication No. H6-12452, Japanese Unexamined Patent Application, Publication No. S59-93448, and the like may be used as the organic antireflective film.

### Resist Film-Providing Step

In the resist film-providing step, a radiation-sensitive resin composition is applied on the resist underlayer film provided in the silicon-containing film-providing step to provide a resist film.

### Radiation-Sensitive Resin Composition

The radiation-sensitive resin composition contains: a base polymer that includes an acid-labile group; an acid generator; and a solvent. In addition, the radiation-sensitive resin composition may contain other component(s) such as an acid diffusion control agent.

The base polymer includes an acid-labile group. The acid-labile group as referred to means a group capable of being dissociated by an action of an acid generated from the acid generator or the like. When the acid-labile group is dissociated, a polar group such as a carboxy group is generated on the base polymer, and consequently a difference of the solubility in a developer solution is caused between the base polymer present at a light-exposed site and the base polymer present at a light-unexposed site.

A polymer typically contained in the radiation-sensitive resin composition may be used as the base polymer that includes an acid-labile group, and a polymer having a structure derived from 1-alkyl-1-cycloalkyl (meth)acrylate, a polymer having a structure derived from 2-cycloalkylpropan-2-yl (meth)acrylate, a polymer having a structure derived from 2-alkyl-2-adamantyl (meth)acrylate, and a polymer having a structure derived from 2-(adamantan-1-yl)propan-2-yl (meth)acrylate are preferred.

The base polymer may also have a structure such as a lactone structure, a cyclic carbonate structure or a sultone structure. When the base polymer has such a structure, the solubility of the resist film in the developer solution may be further improved.

The lower limit of the content of the base polymer in the total solid content of the radiation-sensitive resin composition is preferably 70% by mass, more preferably 75% by mass, and still more preferably 80% by mass.

The acid generator may be contained either in the form of a low molecular weight compound, or in the form of a polymer into which the low molecular weight compound is incorporated as a part of the polymer, or may be in both of these forms. The low molecular weight compound is exemplified by compounds similar to the acid generating agent exemplified in connection with the composition for silicon-containing film formation. Of these, the onium salt compound is preferred, and the sulfonium salt and the tetrahydrothiophenium salt are more preferred.

In a case where the acid generator is the low molecular weight compound, in light of ensuring the sensitivity and the developability of the radiation-sensitive resin composition, the lower limit of the content of the acid generator with respect to 100 parts by mass of the base polymer is preferably 0.1 parts by mass, more preferably 0.5 parts by mass, still more preferably 1 part by mass, and particularly preferably 3 parts by mass. On the other hand, the upper limit of the content is preferably 30 parts by mass, more preferably 20 parts by mass, still more preferably 15 parts by mass, and particularly preferably 10 parts by mass. When the content of the acid generator falls within the above range, the sensitivity and the developability of the radiation-sensitive resin composition may be improved. One, or two or more types of the acid generator may be used.

The solvent is exemplified by solvents similar to those exemplified in connection with the composition for silicon-containing film formation according to the embodiments of the present invention. Of these, the ester solvent and the ketone solvent are preferred, and propylene glycol monomethyl ether acetate and cyclohexanone are more preferred. One, or two or more types of the solvent may be used.

The acid diffusion control agent is exemplified by: nitrogen-containing compounds similar to those exemplified in connection with the composition for silicon-containing film formation; a photodegradable base; and the like.

The photodegradable base is a compound that generates a weak acid upon an exposure. At a light-unexposed site, the photodegradable base exhibits an acid trap function due to an anion thereof and consequently serves as a quencher to trap an acid diffused from a light-exposed site. On the other hand, at the light-exposed site, the photodegradable base generates an acid and the anion thereof disappears, and consequently the photodegradable base loses its acid trap function. Thus, the photodegradable base serves as a quencher only at the light-unexposed site, and accordingly a contrast of the dissociation reaction of the acid-labile group may be improved. The photodegradable base is exemplified by an onium salt compound that is degraded upon an exposure to lose its acid diffusion controllability, and the like. Examples of the onium salt compound include sulfonium salt compounds, iodonium salt compounds, and the like.

The acid diffusion control agent is preferably a photodegradable base, and more preferably triphenylsulfonium salicylate or triphenylsulfonium camphorsulfonate.

The lower limit of the content of the acid diffusion control agent with respect to 100 parts by mass of the base polymer is preferably 0.1 parts by mass, and more preferably 0.3 parts by mass. On the other hand, the upper limit of the content is preferably 10 parts by mass, more preferably 7 parts by mass, and still more preferably 5 parts by mass. When the content of the acid diffusion control agent is greater than the upper limit, the sensitivity of the resulting radiation-sensitive resin composition may be decreased. The acid diffusion control agent may be used alone, or two or more types thereof may be used as a mixture.

As a procedure for applying the radiation-sensitive resin composition, for example, a procedure similar to the application procedure exemplified in connection with the silicon-containing film-providing step may be employed. In addition, the film thickness of the provided resist film is typically no less than 0.01 μm and no greater than 1 μm, and preferably no less than 0.01 μm and no greater than 0.5 μM.

Moreover, after the radiation-sensitive resin composition is applied, prebaking (PB) may be executed to evaporate the solvent in the coating film, as needed. The temperature and time period of the PB may be similar to those of the PB for the silicon-containing film.

Further, a protective film may be provided on the provided resist film such that the resist film is not affected by basic impurities and the like in the environment atmosphere. The protective film is exemplified by protective films disclosed in Japanese Unexamined Patent Application, Publication No. H5-188598, and the like. In addition, in order to prevent outflow of the acid generator and the like from the resist film, a protective film for liquid immersion disclosed in, for example, Japanese Unexamined Patent Application, Publication No. 2005-352384 and the like may be provided on the resist film. It is to be noted that these techniques may be used in combination.

### Exposure Step

In this step, the resist film provided in the resist film-providing step is exposed. In this exposure, for example, an isolated trench (iso-trench) pattern can be formed by carrying out a reduced projection exposure at a desired region through an isolated line (iso-line) pattern mask. Also, the exposure may be carried out at least twice by using desired pattern(s) and mask pattern(s). When the exposure is carried out at least twice, the exposure is preferably carried out continuously. When the exposure is carried out a plurality of times, for example, a first reduced projection exposure is carried out through a line-and-space pattern mask at a desired region, and subsequently a second reduced projection exposure is carried out such that lines cross over the light-exposed sites subjected to the first exposure. The first light-exposed sites are preferably orthogonal to the second light-exposed sites. Due to being orthogonal with each other, a circular contact hole pattern is likely to be formed at a light-unexposed sites surrounded by the light-exposed sites.

The liquid immersion liquid which may be used in the exposure is exemplified by water, a fluorine-containing inert liquid, and the like. It is preferred that the liquid immersion liquid is transparent to the exposure wavelength, and has a temperature coefficient of the refractive index as small as possible such that distortion of an optical image projected onto the film is minimized. In particular, when an ArF excimer laser beam (wavelength: 193 nm) is used as an exposure light source, water is preferably used in light of its availability and ease of handling, in addition to the aforementioned respects. When water is used, a slight amount of an additive may be added which reduces the surface tension of water and provides surfactant power. It is preferred that the additive hardly dissolves the resist layer on the wafer and has a negligible influence on an optical coating of an inferior face of a lens. Distilled water is preferably used.

A radioactive ray which may be used in the exposure may be appropriately selected in accordance with the type of the acid generator contained in the radiation-sensitive resin composition, and is exemplified by electromagnetic waves such as an ultraviolet ray, a far ultraviolet ray, a visible light ray, an EUV ray, an X-ray and a γ-ray; charged particle rays such as an electron beam and an α-ray; and the like. Of these, a far ultraviolet ray, an EUV ray, and an electron beam are preferred, and an ArF excimer laser beam (wavelength: 193 nm), a KrF excimer laser beam (wavelength: 248 nm), an EUV ray, and an electron beam are more preferred. The exposure conditions such as an exposure dose may be appropriately selected in accordance with the formulation of the radiation-sensitive resin composition, the type of the additive, and the like. The pattern-forming method may include a plurality of exposure steps, and light sources employed in the exposures carried out in a plurality of times may be same or different.

Moreover, it is preferred that post exposure baking (PEB) is carried out after the exposure. When the PEB is carried out, a dissociation reaction of the acid-labile group in the radiation-sensitive resin composition can smoothly proceed. The PEB temperature is typically no less than 30° C. and no greater than 200° C., preferably no less than 50° C. and no greater than 170° C., and more preferably no less than 70° C. and no greater than 120° C. The PEB time period is typically no less than 5 sec and no greater than 600 sec, and preferably no less than 10 sec and no greater than 300 sec.

### Development Step

In this step, the resist film exposed in the exposure step is developed using a developer solution, followed by a drying treatment and the like. Thus, an intended resist pattern can be formed.

In a development with an alkali, the developer solution which may be used in the development is exemplified by an aqueous alkali solution prepared by dissolving at least one of alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene, and the like. Of these, an aqueous TMAH solution is preferred, and a 2.38% by mass aqueous TMAH solution is more preferred.

Alternatively, in the case of a development with an organic solvent, the developer solution which may be used in the development is exemplified by an organic solvent such as a hydrocarbon solvent, an ether solvent, an ester solvent, a ketone solvent or an alcohol solvent, etc. Examples of the organic solvent include one, or two or more types of the solvents listed in connection with the solvent of the composition for silicon-containing film formation described above, and the like. Of these, an ester solvent and a ketone solvent are preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass.

An appropriate amount of a surfactant may be added to the developer solution as needed. For example, an ionic or nonionic fluorine-containing surfactant and/or an ionic or nonionic silicon-containing surfactant or the like may be used as the surfactant.

Examples of the development method include: a dipping method in which the substrate is immersed for a given time period in the developer solution charged in a container; a puddle method in which the developer solution is placed to form a dome-shaped bead by way of the surface tension on the surface of the substrate for a given time period to conduct a development; a spray method in which the developer solution is sprayed onto the surface of the substrate; a dynamic dispensing method in which the developer solution is continuously applied onto the substrate that is rotated at a constant speed while scanning with a nozzle for developer solution application at a constant speed; and the like.

The formed resist pattern is preferably washed with a rinse agent after the development. In the case of the development with an alkali, the rinse agent is preferably water, and more preferably pure water. In the case of the development with an organic solvent, the rinse agent is preferably an alcohol solvent or an ester solvent, more preferably a monohydric alcohol solvent having 6 to 8 carbon atoms, and still more preferably 1-hexanol, 2-hexanol, 2-heptanol or methylisobutylcarbinol.

The method for the washing treatment is exemplified by: a spin-coating method in which the rinse agent is continuously applied onto the substrate that is rotated at a constant speed; a dipping method in which the substrate is immersed for a given time period in the rinse agent charged in a container; a spray method in which the rinse agent is sprayed onto the surface of the substrate; and the like.

### Dry-Etching Step

In the dry-etching step, the silicon-containing film is dry-etched by using as a mask, the resist pattern formed after the development step, whereby a silicon-containing pattern is formed. Thereafter, the substrate is dry-etched by using the silicon-containing pattern as a mask, whereby a pattern is formed on the substrate.

The dry-etching may be executed using a well-known dry-etching apparatus. In addition, the etching gas for use in the dry-etching may be appropriately selected in accordance with the elemental composition of the silicon-containing film to be etched, and the like, and examples thereof include fluorine-containing gases such as CHF₃, CF₄, C₂F₆, C₃F₈ and SF₆; chlorine-containing gases such as Cl₂ and BCl₃; oxygen-containing gases such as O₂, O₃ and H₂O; gases such as H₂, NH₃, CO and CO₂; inert gases such as He, N₂ and Ar; and the like. One, or two or more types of these gases may be used.

The etching gas for use in the etching of the silicon-containing film is preferably the fluorine-containing gas, and more preferably a mixture of the fluorine-containing gas with the oxygen-containing gas and the inert gas. The etching gas for use in the etching of the substrate is preferably the oxygen-containing gas, and more preferably a mixture of the oxygen-containing gas with the inert gas.

Further, in a case where the resist underlayer film is provided, in the dry-etching step, the resist underlayer film is etched by using the silicon-containing pattern as a mask, and subsequently the substrate is etched. The etching gas for use in the etching of this resist underlayer film is preferably the oxygen-containing gas, and more preferably a mixture of the oxygen-containing gas with the inert gas.

### EXAMPLES

Hereinafter, the present invention is explained in detail by way of Examples, but the present invention should not be construed as being limited to these Examples. Measuring methods for various types of physical properties are shown below.

### Determination of Weight Average Molecular Weight (Mw) and Number Average Molecular Weight (Mn)

The Mw and the Mn of the polysiloxane compound were determined by gel permeation chromatography (GPC) under the following condition:

columns: “G2000 HXL”×2, “G3000 HXL”×1 and “G4000 HXL”×1 available from Tosoh Corporation;

elution solvent: tetrahydrofuran;

column temperature: 40° C.;

flow rate: 1.0 mL/min;

detector: differential refractometer; and

standard substance: mono-dispersed polystyrene.

### ²⁹Si-NMR Analysis

Samples were prepared by dissolving 2.4 g of each of resin solutions obtained in Examples 1 to 6 and Comparative Example 1, and tris(2,4-pentanedionato)chromium (III) in 1.0 g of deuterated benzene. The samples were each subjected to a ²⁹Si-NMR measurement using a nuclear magnetic resonance apparatus (available from Bruker BioSpin K.K.). Based on the difference between chemical shifts of signals in each spectrum obtained in the ²⁹Si-NMR measurement, a proportion Q (%) of an integrated intensity of a signal due to each silicon atom included in the specific siloxane structures with respect to the total of integrated intensities of signals due to silicon atoms included in the polysiloxane compound was determined. In addition, values of S1 to S4 represented by the following formulae (III) to (VI), respectively, were determined:

S1=(q1)/(q1+q2+q3+q4)×100 (III)

S2=(q2)/(q1+q2+q3+q4)×100 (IV)

S3=(q3)/(q1+q2+q3+q4)×100 (V)

S4=(q4)/(q1+q2+q3+q4)×100 (VI)

wherein in the above formulae (III) to (VI), q1 to q4 were as defined in the above formula (I).

### Synthesis of Polysiloxane Compound

Polysiloxane compounds were each synthesized according to the following method. Compounds used in the synthesis of the polysiloxane compound are shown below.

### Hydrolyzable Silane Compound

M-1: tetramethoxysilane (a compound represented by the following formula M-1)

M-2: phenyltrimethoxysilane (a compound represented by the following formula M-2)

M-3: 4-methylphenyltrimethoxysilane (a compound represented by the following formula M-3)

M-4: methyltrimethoxysilane (a compound represented by the following formula M-4)

M-5: 2-[3-(trimethoxysilyl)propyl]succinic anhydride (a compound represented by the following formula M-5)

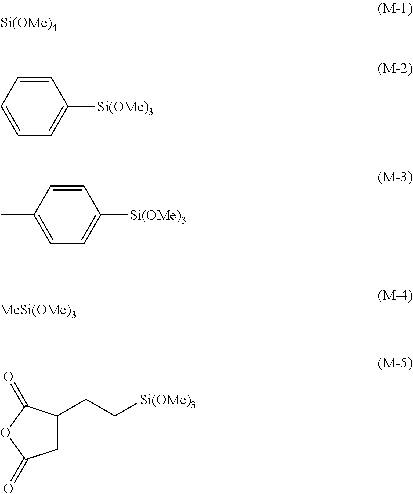

### Catalyst

S-1: tetramethylammonium hydroxide

S-2: tetrabutylammonium hydroxide

S-3: oxalic acid dihydrate

### Example 1

### Synthesis of Polysiloxane Compound (A-1)

An aqueous solution was prepared by dissolving 12.86 g of the catalyst (S-1) in 38.57 g of water with heating. Next, 51.42 g of this aqueous solution and 13.46 g of methanol were charged into a flask, and to the flask were connected a condenser and a dropping funnel containing 30.67 g of the compound (M-1) and 4.44 g of the compound (M-2). Thereafter, the flask was heated to 40° C. in an oil bath, then the compound (M-1) and the compound (M-2) were slowly added dropwise from the dropping funnel, and the reaction was allowed in the mixture at 60° C. for 4 hrs. After completion of the reaction, the flask containing the reaction solution was cooled to 10° C. or below. Separately, 77.56 g of an aqueous maleic acid solution was prepared by dissolving 16.60 g of maleic anhydride in 60.96 g of water, and cooled to 10° C. or below. Next, the reaction solution was added dropwise to this aqueous maleic acid solution, and the mixture was stirred at 10° C. or below for 30 min. To the reaction solution obtained after the stirring, 177.56 g of 1-butyl alcohol was added, and the mixture was transferred to a separatory funnel. Then, washing of this mixture with 355.11 g of water was carried out three times. The reaction solution obtained after the washing with water was transferred to a flask, and to this flask 177.56 g of propylene glycol-1-ethyl ether was further charged. Thereafter, the flask was connected to an evaporator, and then 1-butanol was removed to obtain 71.02 g of a resin solution. The solid content in this resin solution was designated as a polysiloxane compound (A-1). The proportion of the solid content in the obtained resin solution was 15.0% by mass. In addition, the polysiloxane compound (A-1) had a weight average molecular weight (Mw) of 3,100, a value of Q of 86%, and values of Si to S4 of 0%, 13%, 60% and 27%, respectively. Moreover, a value of q represented by the following formula (I) was 0.13, and a value of q′ represented by the following formula (II) was 0.27.

q=(q1+q2)/(q1+q2+q3+q4) (I)

q′=(q4)/(q1+q2+q3+q4) (II)

### Example 2

### Synthesis of Polysiloxane Compound (A-2)

An aqueous solution was prepared by dissolving 12.86 g of the catalyst (S-1) in 38.57 g of water with heating. Next, 51.42 g of this aqueous solution and 13.46 g of methanol were charged into a flask, and to the flask were connected a condenser and a dropping funnel containing 30.67 g of the compound (M-1). Thereafter, the flask was heated to 40° C. in an oil bath, then the compound (M-1) was slowly added dropwise from the dropping funnel, and the reaction was allowed in the mixture at 60° C. for 4 hrs. Thereafter, a dropping funnel containing 4.44 g of the compound (M-2) was connected to the flask, then the compound (M-2) was slowly added dropwise, and the reaction was allowed in the mixture at 60° C. for 2 hrs. After completion of the reaction, the flask containing the reaction solution was cooled to 10° C. or below. Separately, 77.56 g of an aqueous maleic acid solution was prepared by dissolving 16.60 g of maleic anhydride in 60.96 g of water, and cooled to 10° C. or below. Next, the reaction solution was added dropwise to this aqueous maleic acid solution, and the mixture was stirred at 10° C. or below for 30 min. To the reaction solution obtained after the stirring, 177.56 g of 1-butyl alcohol was added, and the mixture was transferred to a separatory funnel. Then, washing of this mixture with 355.11 g of water was carried out three times. The reaction solution obtained after the washing with water was transferred to a flask, and to this flask 177.56 g of propylene glycol-1-ethyl ether was further charged. Thereafter, the flask was connected to an evaporator, and then 1-butanol was removed to obtain 71.02 g of a resin solution. The solid content in this resin solution was designated as a polysiloxane compound (A-2). The proportion of the solid content in the obtained resin solution was 14.0% by mass. In addition, the polysiloxane compound (M-2) had a weight average molecular weight (Mw) of 2,700, a value of Q of 84%, and values of Si to S4 of 1%, 10%, 66% and 23%, respectively. Moreover, a value of q represented by the above formula (I) was 0.11, and a value of q′ represented by the above formula (II) was 0.23.

### Examples 3 to 11

### Synthesis of Polysiloxane Compound (A-3) to (A-11)

Polysiloxane compounds (A-3) to (A-11) were synthesized in a similar manner to Example 1 except that the type and amount of each compound and catalyst used were as shown in Table 1 below. The proportion of the solid content in the resin solution obtained in each Example, as well as an Mw, a value of Q, values of Si to S4, and values of q and q′ of the polysiloxane compound obtained in each Example are shown together in Tables 1 and 2.

### Comparative Example 1

### Synthesis of Polysiloxane Compound (CA-1)

An aqueous catalyst solution was prepared by dissolving 1.28 g of the catalyst (S-3) in 12.85 g of water with heating. Next, 25.05 g of the compound (M-1), 3.63 g of the compound (M-2) and 57.19 g of propylene glycol monoethyl ether were charged into a flask, and to the flask were connected a condenser and a dropping funnel containing the aqueous catalyst solution. Thereafter, the flask was heated to 60° C. in an oil bath, then the aqueous catalyst solution was slowly added dropwise from the dropping funnel, and the reaction was allowed in the mixture at 60° C. for 4 hrs. After completion of the reaction, the flask containing the reaction solution was cooled. Thereafter, the flask was connected to an evaporator, and then methanol formed in the reaction was removed to obtain 97.3 g of a resin solution. The solid content in this resin solution was designated as a polysiloxane compound (CA-1). The proportion of the solid content in the obtained resin solution was 18.0% by mass. In addition, the obtained polysiloxane compound (CA-1) had a weight average molecular weight (Mw) of 2,000, a value of Q of 90%, and values of Si to S4 of 3%, 25%, 54% and 18%, respectively. Moreover, a value of q represented by the above formula (I) was 0.28, and a value of q′ represented by the above formula (II) was 0.18.

TABLE 1

| | | Hydrolyzable silane compound | | | | | | Catalyst | | Solid content | |
|---|---|---|---|---|---|---|---|---|---|---|---|
| | Polysiloxane | | amount | | amount | | amount | | amount | concentration | |
| | compound | type | (mol %) | type | (mol %) | type | (mol %) | type | (mol %) | (mass %) | Mw |
| Example 1 | A-1 | M-1 | 90 | M-2 | 10 | — | — | S-1 | 70 | 15.0 | 3,100 |
| Example 2 | A-2 | M-1 | 90 | M-2 | 10 | — | — | S-1 | 70 | 14.0 | 2,700 |
| Example 3 | A-3 | M-1 | 80 | M-2 | 10 | M-5 | 10 | S-2 | 80 | 16.0 | 2,700 |
| Example 4 | A-4 | M-1 | 80 | M-2 | 10 | M-3 | 10 | S-1 | 70 | 17.5 | 2,500 |
| Example 5 | A-5 | M-1 | 65 | M-2 | 25 | M-4 | 10 | S-2 | 60 | 21.0 | 3,000 |
| Example 6 | A-6 | M-1 | 80 | M-3 | 10 | M-5 | 10 | S-1 | 80 | 18.0 | 2,600 |
| Example 7 | A-7 | M-1 | 75 | M-2 | 15 | M-4 | 10 | S-1 | 50 | 16.0 | 3,800 |
| Example 8 | A-8 | M-1 | 85 | M-3 | 15 | — | — | S-1 | 60 | 17.0 | 3,500 |
| Example 9 | A-9 | M-1 | 75 | M-2 | 10 | M-5 | 15 | S-1 | 85 | 15.5 | 2,000 |
| Example 10 | A-10 | M-1 | 55 | M-2 | 10 | M-4 | 35 | S-2 | 90 | 14.0 | 1,700 |
| Example 11 | A-11 | M-1 | 85 | M-3 | 5 | M-4 | 15 | S-2 | 10 | 17.5 | 2,500 |
| Comparative | CA-1 | M-1 | 90 | M-2 | 10 | — | — | S-3 | 15 | 18.0 | 2,000 |
| Example 1 | | | | | | | | | | | |

TABLE 2

| | Q | S1 | S2 | S3 | S4 | | |
|---|---|---|---|---|---|---|---|
| | (%) | (%) | (%) | (%) | (%) | q | q′ |
| Example 1 | 86 | 0 | 13 | 60 | 27 | 0.13 | 0.27 |
| Example 2 | 84 | 1 | 10 | 66 | 23 | 0.11 | 0.23 |
| Example 3 | 78 | 0 | 9 | 68 | 23 | 0.09 | 0.23 |
| Example 4 | 77 | 0 | 11 | 69 | 20 | 0.11 | 0.20 |
| Example 5 | 61 | 0 | 10 | 64 | 26 | 0.10 | 0.26 |
| Example 6 | 77 | 0 | 9 | 69 | 22 | 0.09 | 0.22 |
| Example 7 | 74 | 0 | 5 | 61 | 34 | 0.05 | 0.34 |
| Example 8 | 83 | 0 | 7 | 63 | 30 | 0.07 | 0.30 |
| Example 9 | 71 | 1 | 17 | 61 | 21 | 0.18 | 0.21 |
| Example 10 | 51 | 2 | 18 | 60 | 20 | 0.20 | 0.20 |
| Example 11 | 85 | 1 | 22 | 55 | 22 | 0.23 | 0.22 |
| Comparative | 90 | 3 | 25 | 54 | 18 | 0.28 | 0.18 |
| Example 1 | | | | | | | |

### Preparation of Composition for Silicon-Containing Film Formation

Each component used in the preparation of the compositions for silicon-containing film formation is shown below.

### Acid Generating Agent

B-1: a compound represented by the following formula (B-1)

B-2: a compound represented by the following formula (B-2)

B-3: a compound represented by the following formula (B-3)

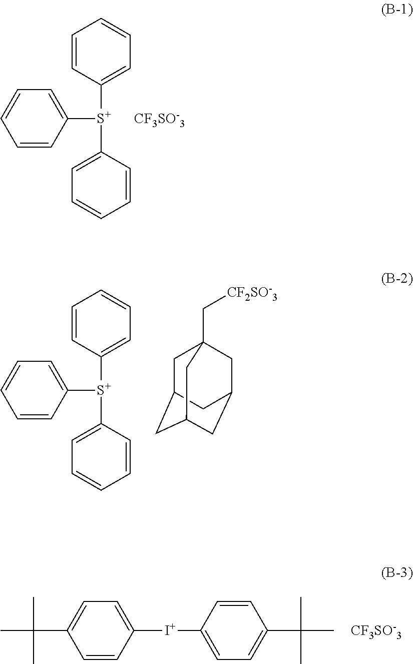

### Solvent

C-1: propylene glycol monoethyl ether

C-2: propylene glycol monomethyl ether acetate

### Example 12

A composition for silicon-containing film formation (L-1) was obtained by mixing 1.93 parts by mass of (A-1) as the polysiloxane compound, 0.06 parts by mass of (B-1) as the acid generating agent, and 93.11 parts by mass of (C-1) and 4.90 parts by mass of (C-2) as the solvent, followed by filtration of this mixed liquid through a 0.2 μm membrane filter.

### Examples 13 to 31 and Comparative Examples 2 to 4

Compositions for silicon-containing film formation (L-2) to (L-20) and (CL-1) to (CL-3) were prepared in a similar manner to Example 12 except that the type and amount of each compound used was as shown in Table 3.

TABLE 3

| | | Polysiloxane | | Acid generating | | | |
|---|---|---|---|---|---|---|---|
| | Composition | compound | | agent | | Solvent | |
| | for silicon- | | amount | | amount | amount of C-1 | amount of C-2 |
| | containing film | | (parts by | | (parts by | (parts by | (parts by |
| | formation | type | mass) | type | mass) | mass) | mass) |
| Example 12 | L-1 | A-1 | 1.93 | B-1 | 0.06 | 93.11 | 4.90 |
| Example 13 | L-2 | A-1 | 1.50 | — | — | 88.65 | 9.85 |
| Example 14 | L-3 | A-1 | 2.50 | B-1 | 0.05 | 90.63 | 6.82 |
| Example 15 | L-4 | A-1 | 1.87 | B-2 | 0.05 | 78.46 | 19.62 |
| Example 16 | L-5 | A-2 | 1.45 | B-1 | 0.02 | 98.53 | — |
| Example 17 | L-6 | A-2 | 2.00 | B-3 | 0.01 | 83.29 | 14.70 |
| Example 18 | L-7 | A-3 | 2.21 | B-1 | 0.05 | 87.97 | 9.77 |
| Example 19 | L-8 | A-3 | 1.84 | B-2 | 0.03 | 73.60 | 24.53 |
| Example 20 | L-9 | A-4 | 1.88 | B-1 | 0.06 | 98.06 | — |
| Example 21 | L-10 | A-4 | 1.65 | B-3 | 0.02 | 83.58 | 14.75 |
| Example 22 | L-11 | A-5 | 1.88 | B-2 | 0.02 | 88.29 | 9.81 |
| Example 23 | L-12 | A-5 | 1.94 | B-1 | 0.06 | 93.10 | 4.90 |
| Example 24 | L-13 | A-6 | 2.05 | B-1 | 0.05 | 88.11 | 9.79 |
| Example 25 | L-14 | A-7 | 2.35 | B-1 | 0.05 | 68.32 | 29.28 |
| Example 26 | L-15 | A-7 | 2.12 | B-2 | 0.03 | 83.17 | 14.68 |
| Example 27 | L-16 | A-8 | 1.68 | B-1 | 0.02 | 78.64 | 19.66 |
| Example 28 | L-17 | A-9 | 1.83 | B-2 | 0.05 | 73.59 | 24.53 |
| Example 29 | L-18 | A-10 | 1.80 | B-1 | 0.02 | 88.36 | 9.82 |
| Example 30 | L-19 | A-10 | 2.15 | B-2 | 0.03 | 97.82 | — |
| Example 31 | L-20 | A-11 | 2.00 | B-1 | 0.05 | 88.16 | 9.80 |
| Comparative | CL-1 | CA-1 | 2.01 | — | — | 91.13 | 6.86 |
| Example 2 | | | | | | | |
| Comparative | CL-2 | CA-1 | 1.85 | B-1 | 0.05 | 98.10 | — |
| Example 3 | | | | | | | |
| Comparative | CL-3 | CA-1 | 2.03 | B-1 | 0.05 | 88.13 | 9.79 |
| Example 4 | | | | | | | |

### Production of Substrate for Evaluation

### Preparation of Radiation-Sensitive Resin Composition (J-1)

Each monomer used in the synthesis of polymers (R-1) and (R-2) is shown below.

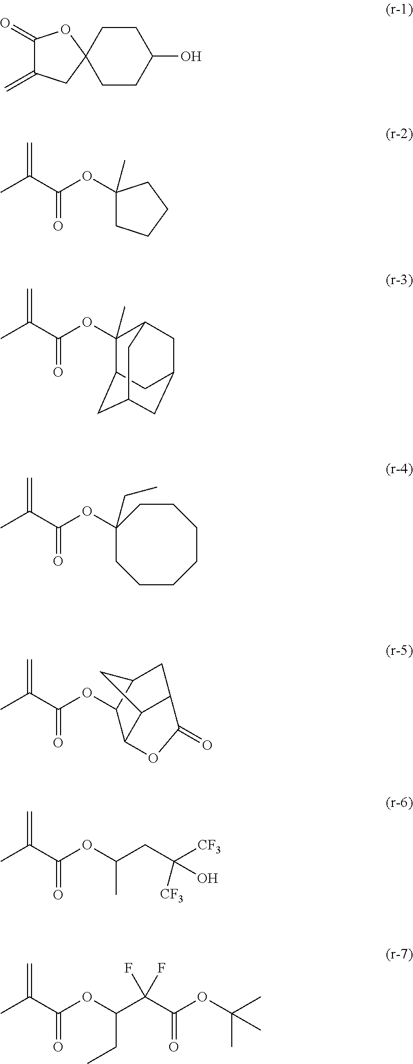

Synthesis of Polymer (R-1)

A monomer solution was prepared by dissolving 4.0 g (10 mol %) of the compound (r-1), 14.8 g (40 mol %) of the compound (r-2), 5.1 g (10 mol %) of the compound (r-3), and 19.5 g (40 mol %) of the compound (r-5) in 60 g of 2-butanone, and further adding 0.7 g of azobisisobutyronitrile (AIBN) thereto. Separately, a 200 mL three-neck flask into which 30 g of 2-butanone was charged was purged with nitrogen for 30 min, and then this reaction vessel was heated to 80° C. with stirring. The monomer solution prepared beforehand was added dropwise to the reaction vessel over 3 hrs through a dropping funnel. The time of the start of the dropwise addition was considered to be the time of the start of the polymerization, and the polymerization reaction was allowed to proceed for 6 hrs. After completion of the polymerization, the polymerization solution was water-cooled to 30° C. or below, then the cooled polymerization solution was poured into 600 g of methanol, and the precipitated white powder was filtered off. The white powder filtered off was washed twice with 150 g of methanol in a slurry form, filtered off again, and dried at 50° C. for 17 hrs to obtain a copolymer as a white powder. The obtained copolymer had an Mw of 12,000 and an Mw/Mn of 1.5, and the yield of the obtained copolymer was 50%. In addition, the result of ¹³C-NMR analysis indicated that the proportions (mol %) of the structural unit derived from the compound (r-1), the structural unit derived from the compound (r-2), the structural unit derived from the compound (r-3), and the structural unit derived from the compound (r-5) were 11, 38, 10 and 41, respectively. The copolymer was designated as polymer (R-1). It is to be noted that the ¹³C-NMR analysis was carried out using JNM-ECX400 available from JEOL, Ltd., and deuterochloroform as a measurement solvent. The proportion of each structural unit in the polymer was calculated based of an area ratio of a peak due to each structural unit in the spectrum obtained in the ¹³C-NMR.

Synthesis of Polymer (R-2)

A solution was obtained by dissolving 60.7 g (60 mol %) of the compound (r-4), 33.1 g (25 mol %) of the compound (r-6), and 18.8 g (15 mol %) of the compound (r-7) in 100 g of 2-butanone. To the solution obtained was added 3.7 g of azobisisobutyronitrile (AIBN) to prepare a monomer solution. Next, a 500 mL three-neck flask into which 100 g of 2-butanone was charged was purged with nitrogen for 30 min. After the purging with nitrogen, this reaction vessel was heated to 80° C. with stirring, and then the monomer solution prepared beforehand was added dropwise thereto over 3 hrs through a dropping funnel. The time of the start of the dropwise addition was considered to be the time of the start of the polymerization, and the polymerization reaction was allowed to proceed for 6 hrs to obtain a polymerization solution. After completion of the polymerization, the polymerization solution was water-cooled to 30° C. or below, then the cooled polymerization solution was poured into 800 g of a mixed solvent of methanol and water (ratio of methanol/water: 19/1) to precipitate a white substance. After the supernatant solution was discarded, the white substance was washed with 800 g of the mixed solvent of methanol and water (ratio of methanol/water: 19/1). Thereafter, the solvent was replaced with propylene glycol monomethyl ether acetate, whereby a solution of a polymer (R-2) was obtained (yield: 66%). This copolymer had a molecular weight (Mw) of 6,700 and an Mw/Mn of 1.6, and the result of ¹³C-NMR analysis indicated that the proportions (mol %) of the structural unit derived from the compound (r-4), the structural unit derived from the compound (r-6), and the structural unit derived from the compound (r-7) was 62, 23 and 15, respectively.

Each component used in the preparation of a radiation-sensitive resin composition (J-1) is shown below.

Acid Generating Agent

b-1: a compound represented by the following formula (b-1)

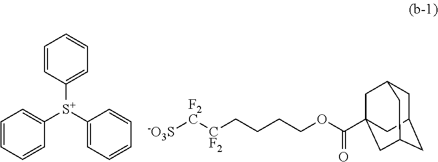

Acid Diffusion Control Agent

(d-1): a compound represented by the following formula (d-1)

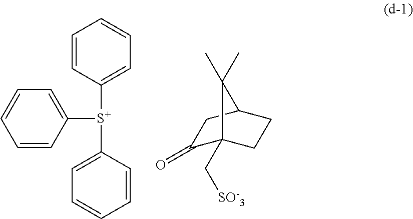

Solvent

(e-1): propylene glycol monomethyl ether acetate

(e-2): cyclohexanone

(e-3): γ-butyrolactone

The radiation-sensitive resin composition (J-1) was prepared by mixing 100 parts by mass of the polymer (R-1), 3 parts by mass of the polymer (R-2), 10 parts by mass of the acid generating agent (b-1), 1.4 parts by mass of the acid diffusion control agent (d-1), and 2,185 parts by mass of the solvent (e-1), 935 parts by mass of the solvent (e-2) and 30 parts by mass of the solvent (e-3), followed by filtration of this mixed liquid through a 0.2 μm membrane filter.

### Formation of Silicon-Containing Film

A material for antireflective film formation (“HM8006” available from JSR Corporation) was applied on the surface of a 12-inch silicon wafer using a spin coater (“CLEAN TRACK ACT12” available from Tokyo Electron Limited), and heated at 250° C. for 60 sec to provide an antireflective film having a film thickness of 100 nm. Each composition for silicon-containing film formation was applied on the surface of this antireflective film using the spin coater, heated at 220° C. for 1 min using a hot plate, and then cooled at 23° C. for 60 sec to provide a silicon-containing film having a film thickness of 30 nm. A film thickness measuring device (“M-2000D” available from J. A. Woollam) was used in the measurement of the film thickness of the silicon-containing film.

### Formation of Resist Pattern

The radiation-sensitive resin composition (J-1) was applied on the surface of the silicon-containing film using the spin coater, heated at 90° C. for 60 sec, and then cooled at 23° C. for 30 sec to provide a resist film having a film thickness of 100 nm. Next, this resist film was exposed through a mask having a mask size for forming a resist pattern with 40 nm line/80 nm pitch, using an ArF Immersion Scanner (“S610C” available from NIKON Corporation) under the optical conditions involving NA of 1.30 and Dipole. After the exposure, the resist film was subjected to PEB at 100° C. for 60 sec using a resist coater/developer (“CLEAN TRACK Lithius Pro-i” available from Tokyo Electron Limited), and cooled at 23° C. for 30 sec. Thereafter, a puddle development was executed at 23° C. for 30 sec by using butyl acetate, and then, rinsing was executed for 10 sec by using methylisobutylcarbinol (MIBC). After the rinsing, spin drying was executed by spinning off for 15 sec at 2,000 rpm, whereby a resist pattern with 40 nm line/80 nm pitch was formed.

Evaluations Measurements were made on the resist pattern formed above according to the following methods, and based on the measurements, the pattern collapse resistance of each composition for silicon-containing film formation and the pattern configuration of a resist pattern formed from each composition for silicon-containing film formation were evaluated. It is to be noted that a scanning electron microscope (“CG-4000” available from Hitachi High-Technologies Corporation) was used in the measurement and observation of the resist pattern.

### Pattern Collapse Resistance

In the formation of the resist pattern, an exposure dose at which a pattern having lines with a line width of 38 nm, and a distance (space) between adjacent lines of 40 nm was formed was defined as an optimum exposure dose. A series of exposures were sequentially executed while decreasing the exposure dose stepwise from the optimum exposure dose as the starting exposure dose, and each line width of lines formed was measured. The line width of the pattern decreased with the decrease of the exposure dose, and the collapse of the resist pattern was found when the line width was smaller than a certain value. Then, a line width corresponding to the minimum exposure dose at which the collapse of the resist pattern was not found was defined as a minimum pre-collapse dimension (nm), and used as an index of the pattern collapse resistance. The pattern collapse resistance was evaluated to be: “A” when the minimum pre-collapse dimension was no greater than 32 nm; “B” when the minimum pre-collapse dimension was greater than 32 nm and no greater than 38 nm; and “C” when the minimum pre-collapse dimension was greater than 38 nm. In the evaluation, “A” and “B” were decided to be acceptable. The results of the evaluation are shown in Table 4.

### Pattern Configuration

The pattern configuration was evaluated to be: “A” when tailing of the cross section of the resist pattern was not found; and “C” when the pattern collapse or the tailing was found. In the evaluation, “A” was decided to be acceptable. The results of the evaluation are shown in Table 4.

### Solvent Resistance of Uncured Film

Each of the compositions for silicon-containing film formation which were prepared in the Examples and Comparative Examples described above was applied on the surface of a 12-inch silicon wafer by using a spin coater (“CLEAN TRACK ACT12” available from Tokyo Electron Limited), and was left to stand at room temperature for 30 min. Next, a thinner (“OK73 thinner” available from Tokyo Ohka Kogyo Co., Ltd.) was applied on the surface of the composition for silicon-containing film formation applied. After being left to stand for 30 sec, the thinner was removed. The thickness of the composition for silicon-containing film formation was measured before and after the application of the thinner by using a high-speed spectroscopic ellipsometer (“M-2000” available from J. A. Woollam), whereby a difference (T₀−T) between a thickness (T₀) before the application and a thickness (T) after the application was determined. A proportion ((T₀−T)/T₀) of the difference (T₀−T) to the thickness (T₀) before the application was defined as an index of the solvent resistance of an uncured film. The solvent resistance of the uncured film was evaluated to be: “A” when the proportion was greater than 80%; “B” when the proportion was greater than 60% and no greater than 80%; and “C” when the proportion was no greater than 60%. In the evaluation, “A” and “B” were decided to be acceptable.

### Storage Stability

Each of the compositions for silicon-containing film formation which were prepared in the Examples and Comparative Examples described above was heated at 40° C. for 1 week. The weight average molecular weight of the polysiloxane compound contained in each composition for silicon-containing film formation was measured before and after the heating, and then a difference (Mwₕ−Mw₀) between the molecular weight (Mwₕ) after the heating and the initial molecular weight (Mw₀) was determined. A proportion ((Mwₕ−Mw₀)/Mw₀) of the difference to the initial molecular weight was defined as an index of the storage stability. The storage stability was evaluated to be: “A” when the proportion was no greater than 20%; “B” when the proportion was greater than 20% and no greater than 30%; and “C” when the proportion was greater than 30%. In the evaluation, “A” and “B” were decided to be acceptable.

TABLE 4

| | Composition | | | Solvent | |
|---|---|---|---|---|---|
| | for silicon- | Pattern | Tailing | resistance | |
| | containing film | collapse | of | of uncured | Storage |
| | formation | resistance | pattern | film | stability |
| Example 12 | L-1 | A | A | A | A |
| Example 13 | L-2 | A | A | A | A |
| Example 14 | L-3 | A | A | A | A |
| Example 15 | L-4 | A | A | A | A |
| Example 16 | L-5 | A | A | A | A |
| Example 17 | L-6 | A | A | A | A |
| Example 18 | L-7 | A | A | A | A |
| Example 19 | L-8 | A | A | A | A |
| Example 20 | L-9 | A | A | A | A |
| Example 21 | L-10 | A | A | A | A |
| Example 22 | L-11 | A | A | A | A |
| Example 23 | L-12 | A | A | A | A |
| Example 24 | L-13 | A | A | A | A |
| Example 25 | L-14 | A | A | A | A |
| Example 26 | L-15 | A | A | A | A |
| Example 27 | L-16 | A | A | A | A |
| Example 28 | L-17 | B | A | B | B |
| Example 29 | L-18 | B | A | B | B |
| Example 30 | L-19 | B | A | B | B |
| Example 31 | L-20 | B | A | B | B |
| Comparative | CL-1 | C | A | C | C |
| Example 2 | | | | | |
| Comparative | CL-2 | C | C | C | C |
| Example 3 | | | | | |
| Comparative | CL-3 | C | C | C | C |
| Example 4 | | | | | |

As shown in Table 4, the silicon-containing films formed by using each of the compositions for silicon-containing film formation of the Examples were superior in the pattern collapse resistance, and achieved reduced tailing of the pattern. On the other hand, the silicon-containing films formed by using each of the compositions for silicon-containing film formation of the Comparative Examples were all inferior in the pattern collapse resistance, and exhibited a tendency that the tailing of the pattern easily occurred.

Further, the compositions for silicon-containing film formation of the Examples were superior in the solvent resistance in an uncured state and the storage stability. On the other hand, the compositions for silicon-containing film formation of the Comparative Examples were inferior in the solvent resistance in an uncured state, and also in the storage stability.

According to the composition for silicon-containing film formation, the pattern-forming method and the polysiloxane compound according to the embodiments of the present invention, inhibited pattern collapse and inhibited tailing of the resist as well as superior solvent resistance before curing can be achieved in multilayer resist processes, in particular, in the case of developments with an organic solvent, while superior storage stability is exhibited. Therefore, these can be suitably used for pattern formation in manufacture of semiconductor devices, and the like in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A composition for silicon-containing film formation comprising:
a polysiloxane compound comprising a structure represented by formula (Q2), a structure represented by formula (Q3) and a structure represented by formula (Q4); and
a solvent: 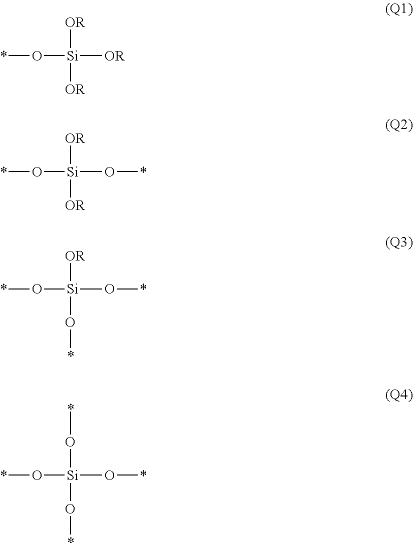
wherein in the formulae (Q1) to (Q4),
each R independently represents a hydrogen atom or a monovalent organic group having 1 to 20 carbon atoms and not comprising a silicon atom; and
* denotes a binding site to a silicon atom,
wherein a value of q calculated according to formula (I) is no greater than 0.25,
q=(q1+q2)/(q1+q2+q3+q4) (I)
wherein q1 to q4 represent integrated intensities of ²⁹Si-NMR signals due to the silicon atoms in the structures represented by the formulae (Q1) to (Q4), respectively, and
wherein a weight average molecular weight of the polysiloxane compound is no greater than 4,000.

2. The composition according to claim 1, wherein the value of q is no greater than 0.2.

3. The composition according to claim 2, wherein the value of q is no greater than 0.15.

4. The composition according to claim 1, wherein a value of q′ calculated according to formula (II) is no less than 0.2,
q′=(q4)/(q1+q2+q3+q4) (II)
wherein in the formula (II), q1 to q4 are as defined in the formula (I).

5. The composition according to claim 4, wherein the value of q′ is no less than 0.25.

6. The composition according to claim 1, wherein a proportion of an amount of the silicon atoms in the structures represented by the formulae (Q1) to (Q4) with respect to a total amount of silicon atoms comprised in the polysiloxane compound is no less than 50 mol %.

7. The composition according to claim 1, wherein the polysiloxane compound is obtained by subjecting a compound represented by formula (1) to condensation using an acid, 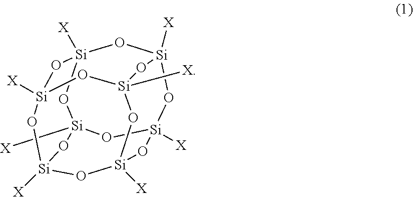
wherein in the formula (1),
X represents —O⁻Z⁺ or a monovalent organic group having 1 to 20 carbon atoms; and
Z⁺ represents a monovalent cation.

8. The composition according to claim 1, wherein the composition is for use in forming a resist underlayer film.

9. A pattern-forming method comprising:
providing a silicon-containing film directly or indirectly on a substrate by using the composition according to claim 1;
providing a resist film on the silicon-containing film by using a resist composition;
exposing the resist film by irradiation with light through a photomask;
developing the exposed resist film to form a resist pattern; and
sequentially dry-etching the silicon-containing film and the substrate using the resist pattern as a mask.

10. A polysiloxane compound comprising:
a structure represented by formula (Q2);
a structure represented by formula (Q3); and
a structure represented by formula (Q4): 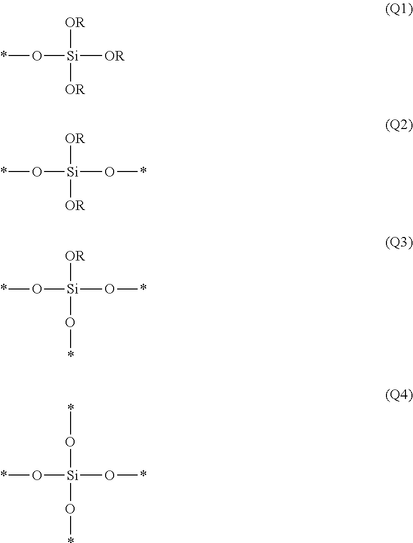
wherein in the formulae (Q1) to (Q4),
each R independently represents a hydrogen atom or a monovalent organic group having 1 to 20 carbon atoms and not comprising a silicon atom; and
* denotes a binding site to a silicon atom,
wherein a value of q calculated according to formula (I) is no greater than 0.25,
q=(q1+q2)/(q1+q2+q3+q4) (I)
wherein q1 to q4 represent integrated intensities of ²⁹Si-NMR signals due to the silicon atoms in the structures represented by the formulae (Q1) to (Q4), respectively, and
wherein a weight average molecular weight of the polysiloxane compound is no greater than 4,000.
